(19) United States
(12) Patent Application Publication
(10) Pub. No.: US 2026/0068113 A1
(43) Pub. Date: Mar. 5, 2026

(54) DISPLAY PANEL, DISPLAY DEVICE

(71) Applicant: Tianma Advanced Display Technology Institute (Xiamen) Co.,Ltd., Xiamen (CN)

(72) Inventors: Zhenyu JIA, Xiamen (CN); Kerui XI, Xiamen (CN); Tianyi WU, Xiamen (CN); Shouzheng WU, Xiamen (CN); Wenqi ZHOU, Xiamen (CN); Zhibo YANG, Xiamen (CN); Yingteng ZHAI, Xiamen (CN); Yunyuan ZHANG, Xiamen (CN)

(21) Appl. No.: 18/924,273

(22) Filed: Oct. 23, 2024

(30) Foreign Application Priority Data
Aug. 28, 2024 (CN) 202411189708.6

(51) Int. Cl. H05K 9/00; G06F 1/16; G09F 9/302; H01L 23/60; H01L 25/16

(52) U.S. Cl. CPC H05K 9/0079; G06F 1/1656; G09F 9/3026; H05K 9/0096

(57) ABSTRACT

A display panel and a display device. The display panel includes a base substrate; an anti-electrostatic layer located on one side of the base substrate; and a first structure located at least on a side of the base substrate away from the anti-electrostatic layer. The anti-electrostatic layer is connected to the first structure via an electrostatic conductive layer; and the electrostatic conductive layer is located at least on a side surface of the base substrate.

### CROSS-REFERENCE TO RELATED APPLICATION

This application claims the priority of Chinese Patent Application No. 202411189708.6, filed on Aug. 28, 2024, the content of which is incorporated by reference in its entirety.

### TECHNICAL FIELD

The present disclosure generally relates to the field of display technologies and, more particularly, relates to a display panel, a display device and a spliced display device.

### BACKGROUND

Display panels usually use an anti-electrostatic ring set inside the base substrate for the electrostatic protection. However, the anti-static ability of the display panel will be very limited if it only relies on the anti-static design of the base substrate itself.

Therefore, how to further optimize the anti-static ability of the display panel is a technical problem that needs to be solved urgently. The disclosed display panels, display devices and spliced display devices are direct to solve such problems and other problems in the art.

### SUMMARY

One aspect of the present disclosure provides a display panel. The display panel includes a base substrate; an anti-electrostatic layer located on one side of the base substrate; and a first structure located at least on a side of the base substrate away from the anti-electrostatic layer. The anti-electrostatic layer is connected to the first structure via an electrostatic conductive layer; and the electrostatic conductive layer is located at least on a side surface of the base substrate.

Another aspect of the present disclosure includes a display device. The display device includes a display panel. The display panel includes a base substrate; an anti-electrostatic layer located on one side of the base substrate; and a first structure located at least on a side of the base substrate away from the anti-electrostatic layer. The anti-electrostatic layer is connected to the first structure via an electrostatic conductive layer; and the electrostatic conductive layer is located at least on a side surface of the base substrate.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates a cross-sectional view of an exemplary display panel according to various embodiments of the present disclosure;

FIG. 2 illustrates an exemplary pixel circuit according to various embodiments of the present disclosure;

FIG. 3 illustrates an exemplary partial structure of the display panel in FIG. 2;

FIG. 4 illustrates another exemplary partial structure of the display panel in FIG. 2;

FIG. 5 illustrates another exemplary display panel according to various embodiments of the present disclosure;

FIG. 6 illustrates an exemplary A1-A2 sectional view of the display panel in FIG. 5;

FIG. 7 illustrates a schematic diagram of an area division of an exemplary display panel according to various embodiments of the present disclosure;

FIG. 8 illustrates an exemplary wiring diagram in FIG. 7;

FIG. 9 illustrate a schematic diagram of another area division of an exemplary display panel according to various embodiments of the present disclosure;

FIG. 10 illustrates a schematic diagram of another area division of an exemplary display panel according to various embodiments of the present disclosure;

FIG. 11 illustrates another exemplary display panel according various embodiments of the present disclosure;

FIG. 12 illustrates another exemplary display panel according to various embodiments of the present disclosure;

FIG. 13 illustrates a B1-B2-sectional view in FIG. 12;

FIG. 14 illustrates another exemplary display panel according to various embodiments of the present disclosure;

FIG. 15 illustrates another cross-sectional view of an exemplary display panel according to various embodiments of the present disclosure;

FIG. 16 illustrates another cross-sectional view of an exemplary display panel according to various embodiments of the present disclosure;

FIG. 17 illustrates another exemplary display panel according to various embodiments of the present disclosure;

FIG. 18 illustrates another exemplary display panel according to various embodiments of the present disclosure;

FIG. 19 illustrates a portion of an exemplary wiring diagram on the back of the substrate of the display panel according to various embodiments of the present disclosure;

FIG. 20 illustrates another exemplary display panel according to various embodiments of the present disclosure;

FIG. 21 illustrates another cross-sectional view of an exemplary display panel according to various embodiments of the present disclosure;

FIG. 22 illustrates another cross-sectional view of an exemplary display panel according to various embodiments of the present disclosure;

FIG. 23 illustrates another cross-sectional view of an exemplary display panel according to various embodiments of the present disclosure;

FIG. 24 illustrates another cross-sectional view of an exemplary display panel according to various embodiments of the present disclosure;

FIG. 25 illustrates another cross-sectional view of an exemplary display panel according to various embodiments of the present disclosure;

FIG. 26 illustrates another cross-sectional view of an exemplary display panel according to various embodiments of the present disclosure;

FIG. 27 illustrates another cross-sectional view of an exemplary display panel according to various embodiments of the present disclosure;

FIG. 28 illustrates another cross-sectional view of an exemplary display panel according to various embodiments of the present disclosure;

FIG. 29 illustrates another cross-sectional view of an exemplary display panel according to various embodiments of the present disclosure;

FIG. 30 illustrates another cross-sectional view of an exemplary display panel according to various embodiments of the present disclosure;

FIG. 31 illustrates another cross-sectional view of an exemplary display panel according to various embodiments of the present disclosure;

FIG. 32 illustrates another cross-sectional view of an exemplary display panel according to various embodiments of the present disclosure;

FIG. 33 illustrates an exemplary protective layer according to various embodiments of the present disclosure;

FIG. 34 illustrates another cross-sectional view of an exemplary display panel according to various embodiments of the present disclosure;

FIG. 35 illustrates another exemplary protective layer according to various embodiments of the present disclosure;

FIG. 36 illustrates another cross-sectional view of an exemplary display panel according to various embodiments of the present disclosure;

FIG. 37 illustrates another exemplary protective layer according to various embodiments of the present disclosure;

FIG. 38 illustrates an exemplary structure of anti-electrostatic layer and electrostatic conduction layer according to various embodiments of the present disclosure;

FIG. 39 illustrates another exemplary structure of anti-electrostatic layer and electrostatic conduction layer according to various embodiments of the present disclosure;

FIG. 40 illustrates another exemplary structure of anti-electrostatic layer and electrostatic conduction layer according to various embodiments of the present disclosure;

FIG. 41 illustrates another exemplary structure of anti-electrostatic layer and electrostatic conduction layer according to various embodiments of the present disclosure;

FIG. 42 illustrates another exemplary structure of anti-electrostatic layer and electrostatic conduction layer according to various embodiments of the present disclosure;

FIG. 43 illustrates another cross-sectional view of an exemplary display panel according to various embodiments of the present disclosure.

FIG. 44 illustrates another cross-sectional view of an exemplary display panel according to various embodiments of the present disclosure;

FIG. 45 illustrates another cross-sectional view of an exemplary display panel according to various embodiments of the present disclosure;

FIG. 46 illustrates an exemplary substrate according to various embodiments of the present disclosure;

FIG. 47 illustrates an exemplary display device according to various embodiments of the present disclosure;

FIG. 48 illustrates an exemplary spliced display device according to various embodiments of the present disclosure;

FIG. 49 illustrates another exemplary spliced display device according to various embodiments of the present disclosure; and

FIG. 50 illustrates another exemplary spliced display device according to various embodiments of the present disclosure.

### DETAILED DESCRIPTION

To better understand the technical solution of the present disclosure, the embodiments of the present disclosure are described in detail below in conjunction with the accompanying drawings.

It should be clear that the described embodiments are only part of the embodiments of the present disclosure, not all of the embodiments. Based on the embodiments of the present disclosure, all other embodiments obtained by ordinary technicians in the field without creative work belong to the scope of protection of the present disclosure.

The terms used in the embodiments of the present disclosure are only for the purpose of describing specific embodiments, and are not intended to limit the present disclosure. The singular forms of “one”, “said” and “the” used in the embodiments of the present disclosure and the attached claims are also intended to include plural forms, unless the context clearly indicates other meanings.

It should be understood that the term “and/or” used in this article is only a description of the association relationship of the associated objects, indicating that there can be three relationships. For example, A and/or B can represent: A exists alone, A and B exist at the same time, and B exists alone. In addition, the character “/” in this article generally indicates that the associated objects before and after are in an “or” relationship.

The present disclosure provides a display panel, and display device and a spliced display device. The display panel may be a light-emitting diode (LED) display panel, an organic light-emitting diode (OLED) display panel, or other types of display panels, such as a micro-LED display panel or a mini-LED display panel, etc.

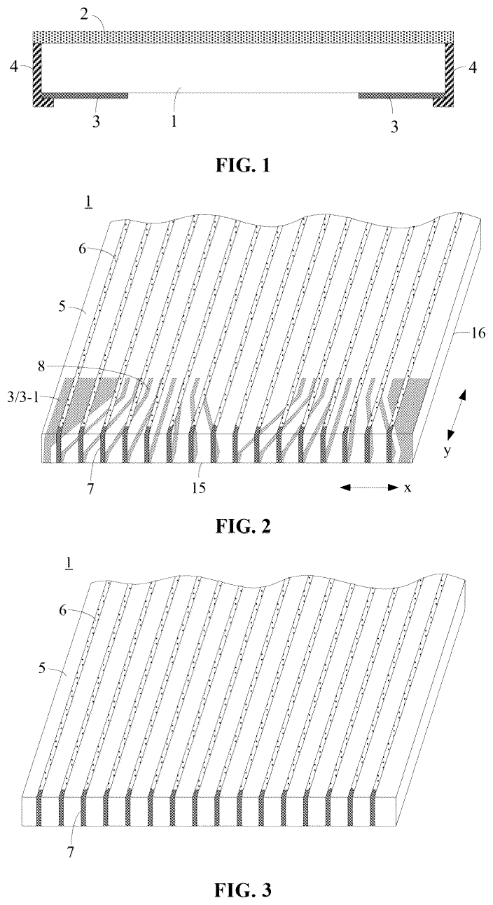

FIG. 1 is a schematic diagram of a cross-sectional view of an exemplary display panel according to various embodiments of the present disclosure. As shown in FIG. 1, the display panel may include a base substrate 1, an anti-electrostatic layer 2, and a first structure 3.

The base substrate 1 may include an array substrate and a light-emitting diode. The array substrate may include various functional circuits and various wirings, and the light-emitting diode may be a micro-LED or a mini-LED.

The anti-electrostatic layer 2 may be located on one side of the base substrate 1, and the anti-electrostatic layer 2 may have the characteristics of light-transmission and electrostatic release. In one embodiment of the present disclosure, the anti-electrostatic layer 2 may have a low resistance characteristic, or a semi-insulating characteristic, which may provide conditions for the flow of static charges. For example, the anti-electrostatic layer 2 may include metal oxide materials, such as indium tin oxide and zinc oxide materials, etc., which may not only have high transparency, but also have relatively low surface resistance, and may effectively conduct static electricity. In another embodiment, the anti-electrostatic layer 2 may also include nanomaterials, such as carbon nanotubes and graphene materials, etc., which may conduct static electricity in a short time and effectively prevent the accumulation of static electricity. Moreover, the anti-electrostatic layer 2 may also be a composite film layer, for example, it may include at least two layers of an anti-fingerprint layer, an anti-glare layer and an anti-reflection layer. In addition, the anti-electrostatic layer 2 may also be treated with Ag-based antistatic liquid or other methods that may make the surface have a semi-insulating electrostatic release effect. Further, in one structure, the anti-electrostatic layer 2 may cover the entire surface of the base substrate 1, and the anti-electrostatic layer 2 may be the outermost film layer of the display panel. For example, the surface where the anti-electrostatic layer 2 is located may be the light-exiting surface of the display panel.

The first structure 3 may be at least located on the side of the substrate 1 away from the anti-electrostatic layer 2. The anti-electrostatic layer 2 may be connected to the first structure 3 through an electrostatic conductive layer 4, and the electrostatic conductive layer 4 may be at least located on the side surface of the base substrate 1.

In the display panel provided by the embodiment of the present disclosure, the anti-electrostatic layer 2, the electrostatic conduction layer 4 and the first structure 3 may form an electrostatic discharge path, and may provide a good anti-static environment for the display panel. The static charge generated on the surface of the display panel may be conducted to the electrostatic conduction layer 4 through the anti-electrostatic layer 2, and then conducted to the first structure 3, and released on the back side of the base substrate 1. Further, the static charge generated on the side surface of the display panel may be conducted to the first structure 3 through the electrostatic conduction layer 4, and released on the back side of the base substrate 1.

In addition, based on the above-mentioned electrostatic discharge path, not only may the anti-electrostatic layer 2 and the electrostatic conduction layer 4 be used to protect the surface of the display panel to a large extent, and to prevent the static charge generated on the surface of the display panel from penetrating into the interior of the base substrate 1, but also, when the static electricity is transmitted on this path, it may only flow from the side surface of the base substrate 1 to the back side through the electrostatic conduction layer 4, and the static electricity may not be transmitted from the inside of the substrate 1. Thus, during its release process, it may also avoid affecting the components and wirings inside the substrates.

Compared with the method of realizing electrostatic protection by relying only on the anti-electrostatic ring of the base substrate itself, the technical solution provided by the embodiments of the present disclosure may make the display panel have stronger anti-electrostatic ability, thereby avoiding the influence of static electricity on the display to a greater extent.

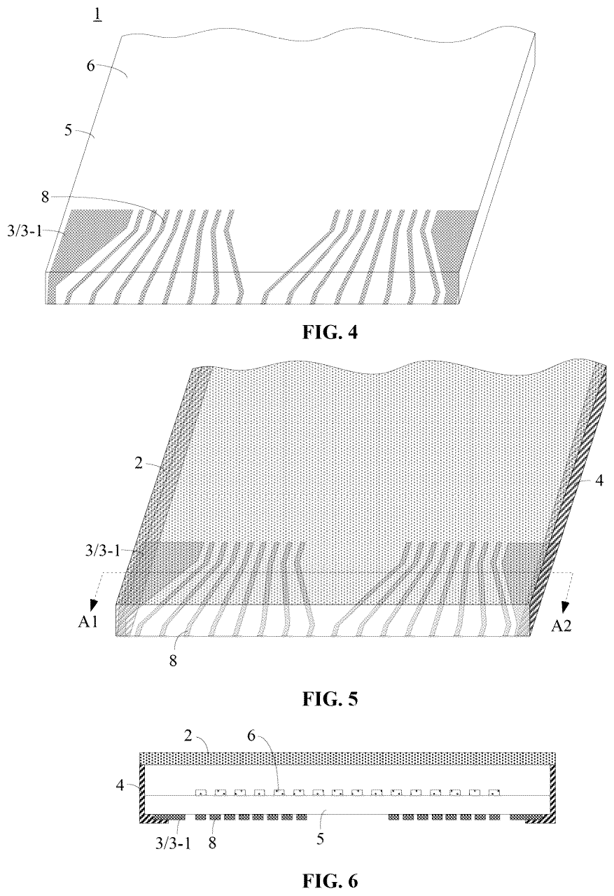

FIG. 2 is a structural schematic diagram of an exemplary display panel provided by an embodiment of the present disclosure. FIG. 3 is a partial structural schematic diagram corresponding to FIG. 2. FIG. 4 is another partial structural schematic diagram corresponding to FIG. 2. FIG. 5 is a structural schematic diagram of another exemplary display panel provided by an embodiment of the present disclosure. FIG. 6 is a cross-sectional view of FIG. 5 along the A1-A2 direction. As shown in FIGS. 2-6, in some embodiments, the base substrate 1 may include a substrate 5, a functional wiring 6, a first side wiring 7 and a fan-out wiring 8.

The functional wiring 6 may be located on the side of the substrate 5 adjacent to the anti-electrostatic layer 2. The functional wiring 6 may be a wiring for realizing the display function, for example, it may include multiple types of wirings, such as data lines, power lines, reset lines, and clock lines, etc.

The fan-out wiring 8 may be located on the side of the substrate 5 away from the anti-electrostatic layer 2. The fan-out wiring 8 may be connected to the driving structure to transmit the signal provided by the driving structure to the functional wiring 6. The driving structure may include a driving chip, a printed circuit board, or a flip chip film, etc.

The functional wiring 6 may be electrically connected to the fan-out wiring 8 through the first side wiring 7, and the first side wiring 7 may be at least located on the side of the substrate 5. In one embodiment of the present disclosure, the first side wiring 7 may be led out from the front of the substrate 5, connected to the functional wiring 6 on the front, and then extended from the side surface of the substrate 5 to the back of the substrate 5, and connected to the fan-out wiring 8 on the back.

The first structure 3 may include a metal part 3-1, which may be located on the side of the substrate 5 away from the anti-electrostatic layer 2. The metal part 3-1 may be arranged on the same layer as the fan-out wiring 8.

The first structure may use the metal part 3-1 on the back side of the substrate 5 to release static electricity. The metal part 3-1 may be further arranged in the same layer as the fan-out wiring 8 on the back side of the substrate 5, that is, the metal part 3-1 and the fan-out wiring 8 may be formed by a same patterning process, which may not only save the process flow, but also the metal part 3-1 may not need to occupy the additional film thickness on the back side of the base substrate 1, and may not affect the overall thickness of the display panel.

It should be noted that, unlike the panel structure in which the substrate is bent to make part of the wiring located on the side and back, the substrate 5 in the embodiment of the present disclosure may not be bent, and the wiring on the side and back of the substrate 5 may be directly formed by the patterning process. For example, the first side wiring 7, the fan-out wiring 8 and the metal part 3-1 may be formed simultaneously by processes such as photolithography, sputtering coating, and chemical vapor deposition, etc. In this panel structure, only the wiring may extend on the side and back of the substrate 5. Because the film thickness of the wiring may be very small, the impact on the frame width and the thickness of the substrate 1 may be very small. Compared with the bending of the substrate, the display panel may achieve a narrower frame or even a frameless design. In addition, because the substrate 5 in the present disclosure does not need to be bent, the optional range of the substrate 5 may be wider, and both flexible substrates, such as polyimide, and rigid substrates, such as glass, may be selected.

In addition, it should be noted that, as described above, the first side wiring 7 and the fan-out wiring 8 may be formed simultaneously by processes such as photolithography, sputtering coating, and chemical vapor deposition, the formed first side wiring 7 and the fan-out wiring 8 may be connected, and the two may not need to be connected by an additional punching process. In other words, the functional wiring 6 may be regarded as connected to the continuous first lead-out line, which may be led out from the front of the substrate 5 and extend from the side of the substrate 5 to the back of the substrate 5, and the part of the first lead-out line located on the front and side of the substrate 5 may be regarded as the first side wiring 7 described in the present disclosure, and the part of the first lead-out line located on the back of the substrate 5 may be regarded as the fan-out wiring 8 described in the present disclosure.

The front side of the substrate 5 described in the embodiment of the present disclosure may be the side of the substrate 5 facing the anti-electrostatic layer 2, and the back side of the substrate 5 may be the side of the substrate 5 away from the anti-electrostatic layer 2.

In addition, it should be noted that the number, film layer position, shape, etc. of the functional wiring 6 and the fan-out wiring 8, etc. shown in the drawings of the embodiments of the present disclosure are schematic illustrations. For example, in the actual structure, the functional wring 6 may be located in multiple metal layers and may be arranged in a variety of ways.

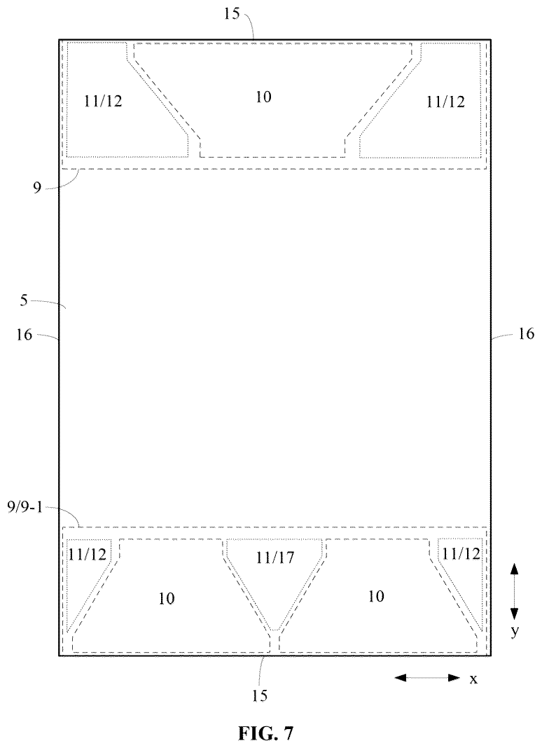

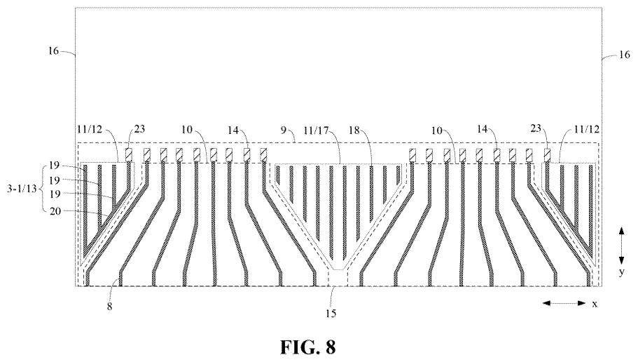

FIG. 7 is a schematic diagram of an area division of an exemplary display panel provided in an embodiment of the present disclosure, and FIG. 8 is a schematic diagram of a wiring distribution of one of the wiring areas 9 in FIG. 7. As shown in FIGS. 7-8, in one embodiment, the substrate 5 may include at least one wiring area 9 on the side away from the anti-electrostatic layer 2. The wiring area 9 may include a fan-out area 10 and a non-fan-out area 11. The fan-out wiring 8 may be located in the fan-out area 10.

The non-fan-out area 11 may include a first non-fan-out area 12. The metal part 3-1 may include a first metal part 13, and the first metal part 13 may be located in the first non-fan-out area 12.

The fan-out wiring 8 may be electrically connected to a fan-out pin 14. In a single fan-out area 10, the fan-out wiring 8 may converge when extending toward the fan-out pin 14 such that, in the direction along the fan-out wiring 8 pointing to the fan-out pin 14, the width of at least a part of the fan-out area 10 in the first direction x may become smaller, and then there may be some blank areas on both sides of the fan-out area 10, which may be the non-fan-out areas 11 mentioned above.

Based on this, the embodiment of the present disclosure may choose to design at least a part of the metal part 3-1 in the non-fan-out area 11 such that this part of the metal part 3-1 may not only play the role of releasing static electricity, but also be used to improve the uniformity of the patterning process of the wiring area 9, such as improving the etching uniformity of the wiring area 9, which may help to make the quality of the formed fan-out wiring 8 better.

In one embodiment, in combination with FIG. 2, FIG. 7 and FIG. 8, the substrate 5 may include a first edge 15 extending along the first direction x and a second edge 16 extending along the second direction y. The first direction x may intersect with the second direction y. At least a portion of the first side wiring 7 may be electrically connected to the fan-out wiring 8 on one side of the first edge 15.

The first non-fan-out area 12 and the fan-out area 10 may be arranged along the first direction x. The first non-fan-out area 12 may be adjacent to the second edge 16. For example, the first metal part 13 may be adjacent to the second edge 16. In this way, the electrostatic conductive layer 4 may be directly connected to the first metal part 13 at the second edge 16. First, the connection may be more convenient. Second, the electrostatic conductive layer 4 may not need to extend a large distance on the back of the substrate 1, shortening the electrostatic discharge path. Accordingly, the static electricity may be transmitted to the first metal part 13 faster and conducted away through the first metal part 13.

In one embodiment of the present disclosure, the non-fan-out area 11 may include two first non-fan-out areas 12. The two first non-fan-out areas 12 may be respectively arranged adjacent to the two second edges 16 such that the electrostatic conductive layer 4 may be connected to the first metal part 13 on both sides of the substrate 5, and the static electricity may be released faster.

Further, referring to FIG. 7 and FIG. 8, the wiring area 9 may include a first wiring area 9-1. The first wiring area 9-1 may include at least two fan-out areas 10 arranged along the first direction x. In the first wiring area 9-1, the non-fan-out area 11 may also include at least one second non-fan-out area 17, and the second non-fan-out area 17 may be located between adjacent fan-out areas 10. To further improve the uniformity of the patterning process of the wiring area 9, a dummy metal layer 18 may be provided in the second non-fan-out area 17.

In one embodiment, referring to FIG. 8, the first metal part 13 may include a plurality of first wirings 19. The plurality of first wirings 19 may be electrically connected to the second wiring 20, and the second wiring 20 may be connected to the first pin 23.

The fan-out wiring 8 may be a linear structure. By designing the first metal part 13 as a linear structure, the first metal part 13 and the fan-out wiring 8 may be similar in shape, and the first metal part 13 may have a better effect on improving the uniformity of the patterning process in the wiring area 9. The first metal part 13 may be connected to the first pin 23, and the static electricity on the electrostatic release path where the anti-electrostatic layer 2 is located may be eventually conducted to the driving structure bound to it through the first pin 23, and then conducted away through the driving structure.

Further, referring to FIG. 8, the second wiring 20 may extend from between the first wiring 19 and the fan-out wiring 8 to the first pin 23 and to be electrically connected with the first pin 23 such that the setting position of the first pin 23 may be closer to the fan-out pin 14, and the overall arrangement of the pins may be tighter. Accordingly, it may be more convenient to bond the pins to the driving structure.

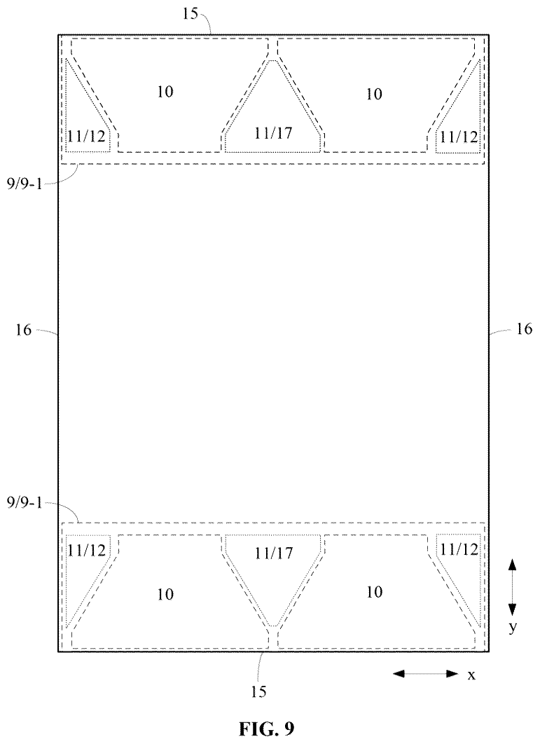

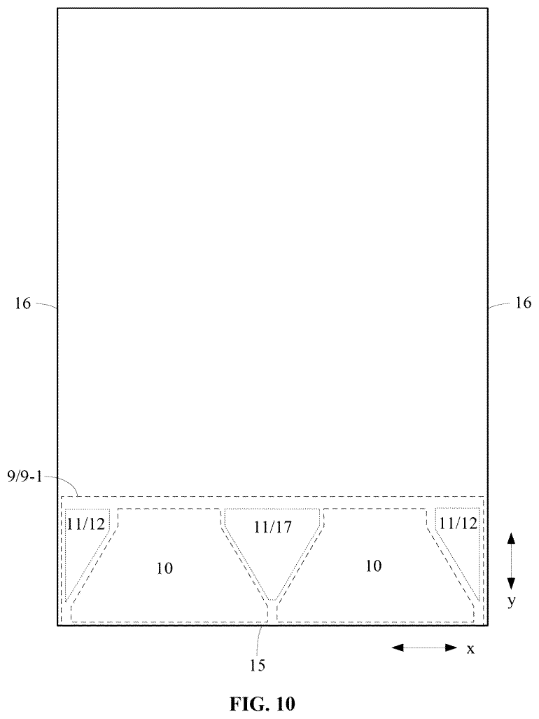

It should be noted that the number of wiring areas 9 in the embodiment of the present disclosure is not specifically limited. For example, referring to FIG. 7 and FIG. 9 which is another schematic diagram of the area division of the display panel according to one embodiment of the present disclosure, the back side of the substrate 5 may have two wiring areas 9. Further, referring to FIG. 7, the distribution of the fan-out area 10 and the non-fan-out area 11 in the two wiring areas 9 may be different, or, referring to FIG. 9, the distribution of the fan-out area 10 and the non-fan-out area 11 in the two wiring areas 9 may be the same. In another embodiment, as shown in FIG. 10, which is another exemplary schematic diagram of the area division of the display panel according to one embodiment of the present disclosure, the back side of the substrate 5 may also include only one wiring area 9.

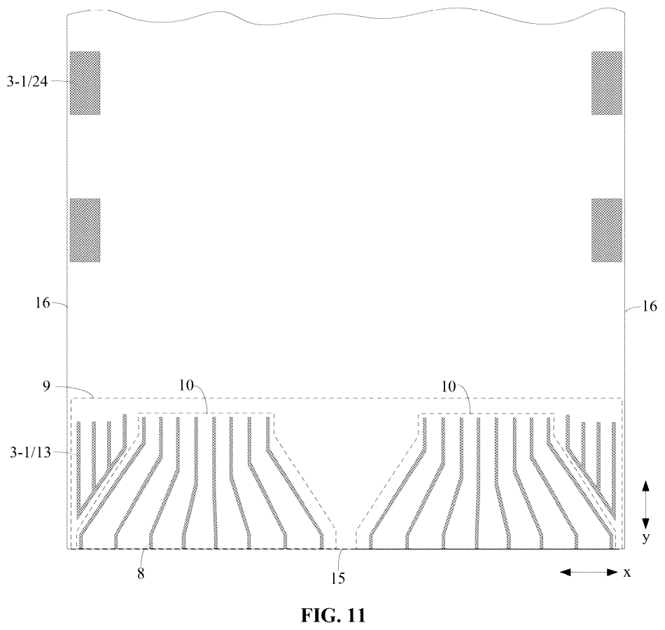

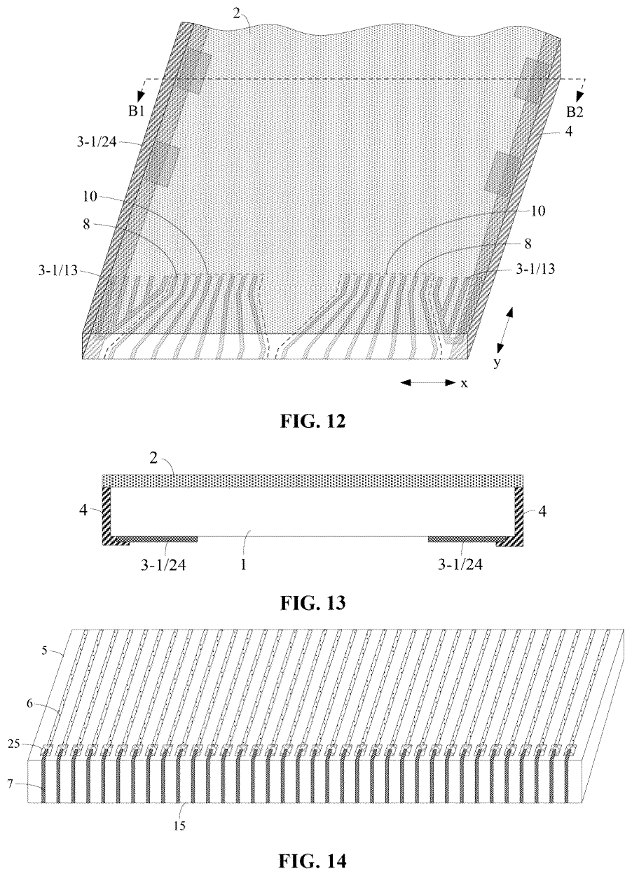

FIG. 11 is a structural schematic diagram of another exemplary display panel provided by an embodiment of the present disclosure. FIG. 12 is a structural schematic diagram of another exemplary display panel provided by an embodiment of the present disclosure. FIG. 13 is a B1-B2-sectional view of FIG. 12. As shown in FIGS. 11-13, in some embodiments, the substrate 5 may include a first edge 15 extending along a first direction x and a second edge 16 extending along a second direction y. The first direction x may intersect with the second direction y. At least a part of the first side edge wiring 7 may be electrically connected to the fan-out wiring 8 on one side of the first edge 15.

The substrate 5 may include a fan-out area 10 on a side away from the anti-electrostatic layer 2, and the fan-out wiring 8 may be located in the fan-out area 10. The metal part 3-1 may include a second metal part 24. The second metal part 24 may be adjacent to the second edge 16, and the second metal part 24 may not be arranged with the fan-out area 10 along the first direction x.

In one embodiment, the second metal part 24 may be located in an area outside the wiring area 9 and arranged along the second edge 16. For example, in combination with the position of the wiring area 9 shown in FIG. 7, the substrate 5 may be provided with wiring areas 9 on one side of the two first edges 15, and the second metal portion 24 may be located between the two wiring areas 9, and arranged along the two second edges 16 at the positions of the two second edges 16. In another embodiment, in combination with the position of the wiring area 9 shown in FIG. 10, the substrate 5 may be provided with a wiring area 9 only on one side of the first edge 15, and the second metal part 24 may be located on the side of the wiring area 9 facing the first edge 15 on the opposite side, and arranged along the two second edges 16 at the positions of the two second edges 16.

Arranging some second metal parts 24 in the area outside the wiring area 9 may disperse the static electricity in the electrostatic conductive layer 4 and conduct it to the first metal part 13 and the second metal part 24. Accordingly, the static electricity release path may be increased, and the release rate may be improved.

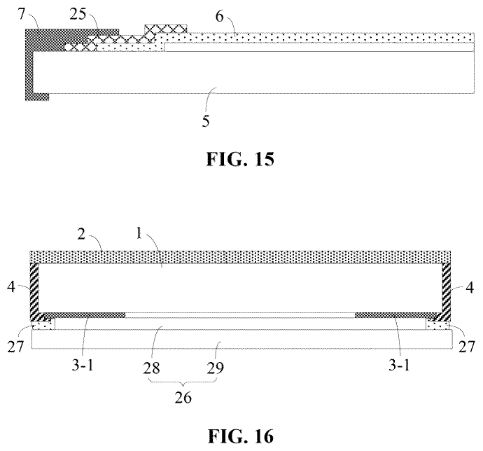

FIG. 14 is a structural schematic diagram of another exemplary display panel provided in an embodiment of the present disclosure, and FIG. 15 is another exemplary cross-sectional view of the display panel provided in an embodiment of the present disclosure. As shown in FIGS. 14-15, in one embodiment, the substrate 5 may include a first edge 15.

The base substrate 1 may also include a connection portion 25, which may be located on a side of the substrate 5 adjacent to the anti-electrostatic layer 2 and adjacent to the first edge 15. Among them, the functional wiring 6 may be electrically connected to the connection portion 25, and at least a portion of the first side wiring 7 may be led out from the connection portion 25 and extend from the side where the first edge 15 is located to be electrically connected to the metal part 3-1.

As mentioned above, the functional wiring 6 may be located in different metal layers. After the connection portion 25 is set, no matter which metal layer the functional wiring 6 is located in, it may be connected to the connection portion 25 near the first edge 15, and then the first side wiring 7 may be led out from the connection portion 25. In this way, the first side wiring 7 led out may be wired separately, and the metal layer where the first side wiring 7 may be located may not be restricted by the metal layer where the functional wiring 6 is located. Accordingly, all the first side wirings 7 may be formed by the same patterning process.

It should be noted that the film layer positions of the functional wiring 6 and the connection portion 25 shown in FIG. 15 are only schematic illustrations. In one embodiment of the present disclosure, the metal layer where the connection portion 25 is located may be located on the side of the metal layer where the functional wiring 6 is located away from the substrate 5, but the functional wiring 6 may be located in different metal layers. When the functional wirings 6 in different metal layers extend to the vicinity of the first edge 15, the connection portion 25 may be led out above it, and then the first side wiring 7 may be led out above the connection portion 25.

FIG. 16 is a cross-sectional view of another exemplary display panel provided in an embodiment of the present disclosure. As shown in FIG. 16, in one embodiment, the display panel may also include a second structure 26, and the second structure 26 may be at least located on the side of the metal part 3-1 away from the anti-electrostatic layer 2.

The electrostatic conductive layer 4 and/or the metal part 3-1 may be also connected to the second structure 26 through the first conductive connection structure 27 such that the electrostatic energy on the electrostatic conductive layer 4 and/or the metal part 3-1 may be further conducted to the second structure 26. Accordingly, a portion of the static electricity may be conducted away through the second structure 26, and the electrostatic release speed may be accelerated.

In one embodiment of the present disclosure, the first conductive connection structure 27 may include a conductive paste, such as a silver paste. The conductive paste may have conductive properties and a certain viscosity, and may be firmly attached to the surface of the electrostatic conductive layer 4, the metal part 3-1 and the second structure 26, thereby achieving a stable connection.

In an embodiment of the present disclosure, the first conductive connection structure 27 may be arranged at least partially around the edge of the base substrate 1, or may be arranged only at the location where the metal part 3-1 is arranged, but not at the location where the side wiring is arranged, so as to prevent the side wiring from short-circuiting.

In one embodiment of the present disclosure, the second structure 26 may include at least one of a heat dissipation structure, a support structure, a backplane and a frame. For example, referring to FIG. 16, the second structure 26 may include a heat dissipation structure 28 and a support structure 29. The heat dissipation structure 28 may include a heat spreader and/or a heat spreader glue. The heat spreader may be an aluminum plate, a stainless steel plate or a copper plate, etc., and the heat spreader glue may be a copper glue, etc. These structures may have good electrostatic release capabilities and may quickly conduct away static electricity. The support structure 29 may include a reinforcement plate, or a support module, etc.

The heat dissipation structure, the support structure, the back plate and the frame may usually be the original structures in the display panel. The second structure 26 may include at least one of these structures, which means that the original structure in the display panel may be used to release static electricity.

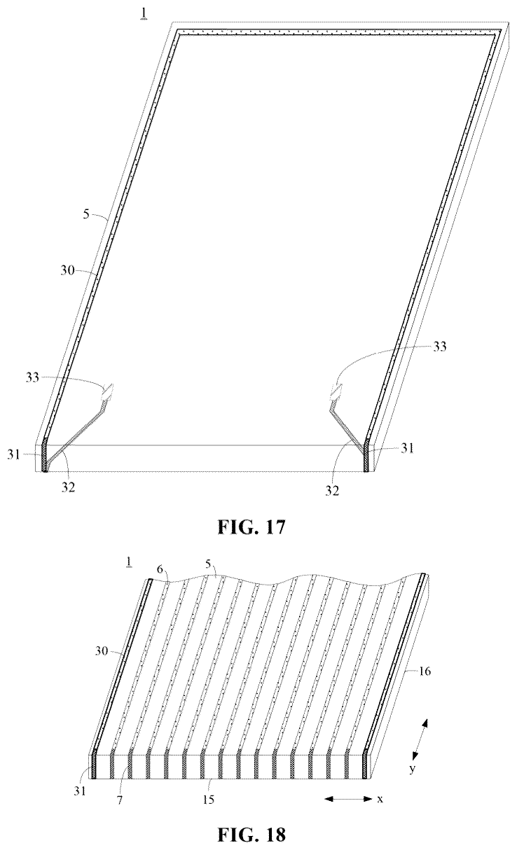

FIG. 17 is a structural schematic diagram of another exemplary display panel provided by one embodiment of the present disclosure. In one embodiment, as shown in FIG. 17, the base substrate 1 may include a substrate 5, an electrostatic ring 30, a second side wiring 31 and a first connection line 32.

The electrostatic ring 30 may be located on the side of the substrate 5 adjacent to the anti-electrostatic layer 2 and extend around the edge of the base substrate 1. The first connection line 32 may be located on the side of the substrate 5 away from the anti-electrostatic layer 2 and may be electrically connected to the second pin 33. The second pin 33 may be used to electrically connect to the driving structure and receive the signal provided by the driving structure. The electrostatic ring 30 may be connected to the first connection line 32 through the second side wiring 31, and the second side wiring 31 may be at least located on the side of the substrate 5.

In this structure, the base substrate 1 itself may also use the electrostatic ring 30 for anti-electrostatic. The static electricity entering from the side of the base substrate 1 may be conducted to the second side wiring 31 through the electrostatic ring 30, and then to the first connection line 32, and may be conducted away through the driving structure bound to the second pin 33.

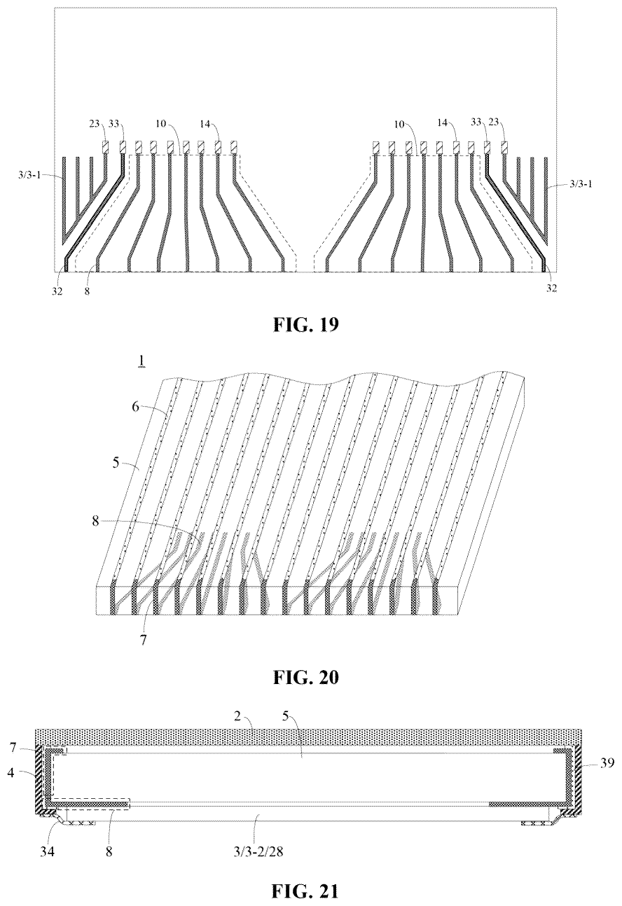

FIG. 18 is a structural schematic diagram of another exemplary display panel provided by an embodiment of the present disclosure. FIG. 19 is a schematic diagram of a wiring division on the back of the base substrate according to one embodiment of the present disclosure. As shown in FIGS. 18-19 and referring to FIG. 17, in one embodiment, the base substrate 1 may also include a functional wiring 6, a first side wiring 7 and a fan-out wiring 8.

The functional wiring 6 may be located on the side of the substrate 5 adjacent to the anti-electrostatic layer 2, and the fan-out wiring 8 may be located on the side of the substrate 5 away from the anti-electrostatic layer 2. The functional wiring 6 may be connected to the fan-out wiring 8 through the first side wiring 7, and the first side wiring 7 may be at least located on the side of the substrate 5.

The first structure 3 may include a metal part 3-1, which may be located on the side of the substrate 5 away from the anti-electrostatic layer 2, and the metal part 3-1 may be arranged on the same layer as the fan-out wiring 8. The first connection line 32 may extend from the metal part 3-1 and the fan-out wiring 8 to be electrically connected to the second pin 33.

In this way, the first connection line 32 connected to the electrostatic ring 30 may not be spaced between the metal part 3-1 and the edge of the substrate 5, and may not hinder the connection between the metal part 3-1 and the anti-electrostatic layer 2.

Further, referring to FIG. 18, the metal part 3-1 may be electrically connected to the first pin 23. The first pin 23 may be used to be electrically connected to the driving structure to receive the signal provided by the driving structure. In one embodiment of the present disclosure, the driving structure may provide the same voltage to the first pin 23 and the second pin 33, or it may provide different voltages. When the driving structure provides different voltages to the first pin 23 and the second pin 33, in one embodiment of the present disclosure, the voltage provided by the driving structure to the first pin 23 may be greater than the voltage provided by the driving structure to the second pin 33.

In the display panel provided by the embodiments of the present disclosure, the electrostatic discharge path from the anti-electrostatic layer 2 to the metal part 3-1 may be the main path for anti-electrostatic, thus the signal provided by the driving structure to the first pin 23 may be slightly larger, thereby enhancing the speed and effect of electrostatic discharge on the main path.

In one embodiment, the first structure 3 may be electrically insulated from the electrostatic ring 30. Taking the first structure 3 including the metal part 3-1 as an example, the structure on the electrostatic discharge path where the metal part 3-1 is located and the structure on the electrostatic discharge path where the electrostatic ring 30 is located may not contact each other, and may be electrically insulated from each other. These two electrostatic discharge paths may be two independent paths, thereby preventing static electricity from being transmitted to the electrostatic ring 30 when transmitting on the electrostatic discharge path where the anti-electrostatic layer 2 is located, causing static electricity to enter the interior of the base substrate, thereby reducing the risk of electrostatic damage to the wiring and devices inside the base substrate 1.

FIG. 20 is a structural schematic diagram of another exemplary display panel provided by one embodiment of the present disclosure. FIG. 21 is another cross-sectional structural schematic diagram of an exemplary display panel provided by one embodiment of the present disclosure. As shown in FIG. 20 and FIG. 21, the base substrate 1 may include a substrate 5, a functional wiring 6, a first side wiring 7, and a fan-out wiring 8.

The functional wiring 6 may be located on the side of the substrate 5 adjacent to the anti-electrostatic layer 2. The fan-out wiring 8 may be located on the side of the substrate 5 away from the anti-electrostatic layer 2. The functional wiring 6 may be electrically connected to the fan-out wiring 8 through the first side wiring 7. The first side wiring 7 may be at least located on the side of the substrate 5.

The first structure 3 may include a first sub-structure 3-2. The first sub-structure 3-2 may be located on the side of the fan-out wiring 8 away from the substrate 5.

Under such a structure, the static electricity on the electrostatic conductive layer 4 may eventually be conducted away through the first sub-structure 3-2. The first sub-structure 3-2 may be some existing structures in the display panel, such as a heat spreader, a reinforcement sheet, etc., and there may be no need to form a new structure as the first substructure.

In one embodiment, the first substructure 3-2 may include at least one of a heat dissipation structure, a support structure and a backplane. For example, in one embodiment of the present disclosure, referring to FIG. 21, the first substructure 3-2 may include a heat dissipation structure 28, and the heat dissipation structure 28 may include a heat spreader and/or a heat spreader glue. The heat spreader may be an aluminum plate, a stainless steel plate or a copper plate, etc., and the heat spreader glue may be a copper glue, etc. These structures may have good electrostatic discharge capabilities and may quickly conduct away static electricity.

The heat dissipation structure, the support structure and the backplane may usually be the original structures in the display panel. The first substructure 3-2 may include at least one of these structures, which may mean that the original structures in the display panel may be used to release static electricity.

In another embodiment, referring to FIG. 21, the electrostatic conductive layer 4 may be connected to the first substructure 3-2 through the second conductive connection structure 34 such that the electrostatic conductive layer 4 may not need to extend too far on the back of the substrate 5 to contact the first substructure 3-2. Accordingly, the risk of short-circuiting the electrostatic transmission layer 4 and the fan-out wiring 8 may be reduced.

Further, the portion of the second conductive connection structure 34 that is connected to the electrostatic conductive layer 4 may be located on the side of the electrostatic conductive layer 4 away from the base substrate 1. That is, the second conductive connection structure 34 may be formed after the electrostatic conductive layer 4 is formed, thereby further reducing the risk of short-circuiting the second conductive connection structure 34 and the fan-out wiring 8.

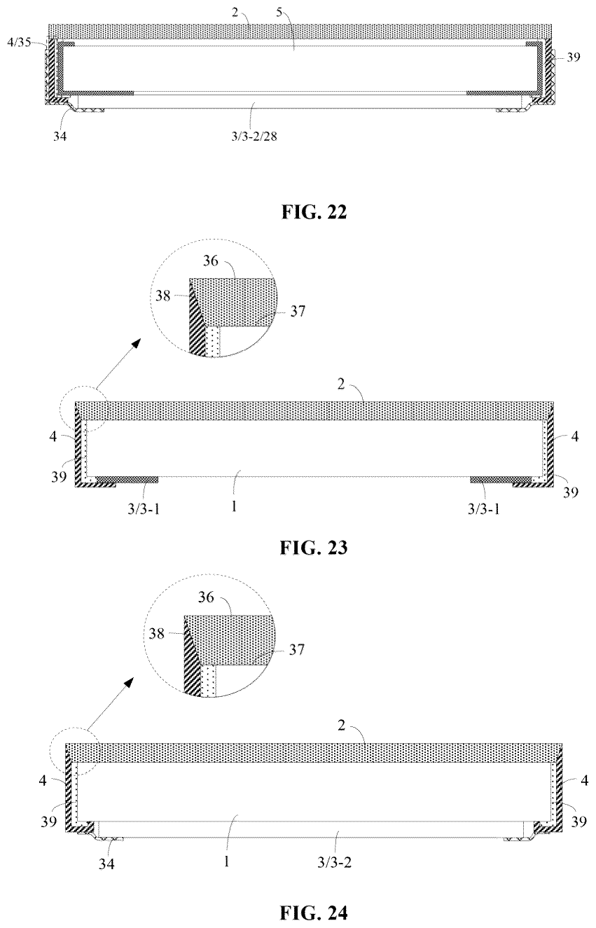

FIG. 22 is another cross-sectional structural schematic diagram of an exemplary display panel provided by one embodiment of the present disclosure. As shown in FIG. 22, the electrostatic conductive layer 4 may include a first sub-division 35. The first sub-division 35 may be located on the side of the base substrate 1.

A portion of the second conductive connection structure 34 may also be located on the side of the first sub-division 35 away from the base substrate 1, and then may form a connection with the side of the electrostatic conductive layer 4 to increase the connection area between the two, thereby increasing the reliability of the connection of the electrostatic release path and improving the electrostatic conduction capability.

In one embodiment of the present disclosure, when the second conductive connection structure 34 is located on the side of the base substrate 1 away from the anti-electrostatic layer 2, the second conductive connection structure 34 may be arranged in a whole circle around the edge of the substrate 1. In another embodiment, the display panel may include at least two second conductive connection structures 34, and the second conductive connection structure 34 may extend in a strip shape along the second direction y. For example, when the first side edge wiring 7 is provided on one side of the first edge 15 of the substrate 5, and the first side edge wiring 7 may not be provided on one side of the second edge 16, the second conductive connection structure 34 may extend along the second edge 16 on the side of the second edge 16. Alternatively, the display panel may also include a plurality of second conductive connection structures 34 spaced apart from each other, and the plurality of second conductive connection structures 34 may be arranged along the edge of the substrate 5.

When a portion of the second conductive connection structure 34 is also located on the side of the first sub-section 35 away from the base substrate 1, the setting position of the second conductive connection structure 34 may be related to the setting position of the electrostatic conductive layer 4. For example, when the electrostatic conductive layer 4 is arranged in a full circle around the base substrate 1, the second conductive connection structure 34 may be arranged in a full circle around the edge of the base substrate 1, or may extend along the second edge 16 only on one side of the second edge 16. When the electrostatic conductive layer 4 is arranged only on one side of the second edge 16, the second conductive connection structure 34 may also be arranged only on one side of the second edge 16.

In one embodiment, the second conductive connection structure 34 may include a copper foil. The copper foil may be bonded and fixed to the electrostatic conductive layer 4 and the first substructure 3-2.

The copper foil may have good ductility and may be plastically deformed and not easily broken when subjected to external force. Therefore, the connection reliability of the entire electrostatic discharge path may be improved by selecting the copper foil to connect the electrostatic conductive layer 4 and the first substructure 3-2.

In one embodiment, the square resistance of the anti-electrostatic layer 2 may be greater than or equal to 104 ohms/square and less than or equal to 109 ohms/square. For materials that may play an anti-static role, when the square resistance of the anti-electrostatic layer 2 is within the above range, the anti-electrostatic layer 2 may have a low resistance characteristic, or a semi-insulating characteristic. The anti-electrostatic layer 2 may have a smaller obstruction to the flow of static charges, and its electrostatic charge release ability may be better. Static charges may move and conduct faster in the anti-electrostatic layer 2, thereby accelerating the release of static charges.

In another embodiment, the square resistance of the electrostatic conductive layer 4 may be greater than or equal to 104 ohms/square and less than or equal to 109 ohms/square. When the square resistance of the electrostatic conductive layer 4 is within such a range, the electrostatic conductive layer 4 may also have a low resistance characteristic, and the electrostatic conductive layer 4 may have a smaller obstruction to the flow of static charges such that the static electricity may be conducted to the first structure 3 faster and released through the first structure 3.

In one embodiment, the square resistance of the electrostatic conductive layer 4 may be smaller than the square resistance of the electrostatic protective layer 2. At this time, the electrostatic conductive layer 4 may have a smaller obstruction effect on the flow of charge, and the transmission rate of static electricity on the electrostatic conductive layer 4 may be faster, which may further reduce the risk of static electricity entering the inside of the base substrate 1 from the side of the base substrate 1 during the transmission process.

FIG. 23 is another cross-sectional structural schematic diagram of an exemplary display panel provided by an embodiment of the present disclosure. FIG. 24 is another cross-sectional structural schematic diagram of an exemplary display panel provided by an embodiment of the present disclosure. As shown in FIG. 23 and FIG. 24, the edge portion of the electrostatic protective layer 2 may protrude from the base substrate 1, and the electrostatic conductive layer 4 may be at least connected to the protruding portion of the electrostatic protective layer 2 such that the connection between the two will be more convenient.

In one structure, the base substrate 1 may have a first positive projection on the electrostatic protective layer 2, and each edge of the first positive projection may be spaced from the edge adjacent to it in the electrostatic protective layer 2, that is, relative to the base substrate 1, the electrostatic protective layer 2 may be expanded outward in a full circle. Accordingly, so no matter whether the electrostatic conductive layer 4 is arranged around the base substrate 1 or only in a local position, it may be conveniently connected to the protruding portion of the electrostatic protective layer 2.

The interval between the edge of the first positive projection and the edge adjacent to it in the electrostatic protective layer 2 may be greater than or equal to the thickness of the electrostatic conductive layer 4 to leave enough accommodation space for the electrostatic protective layer 2 such that the electrostatic conductive layer 4 may only be located in the area covered by the electrostatic protective layer 2. The thickness of the electrostatic conductive layer 4 may be regarded as, for this portion of the electrostatic conductive layer 4 located on the side of the base substrate 1, the thickness of this portion of the electrostatic conductive layer 4 along the direction parallel to the plane where the base substrate 1 is located. Further, the intervals between different edges of the first positive projection and the edges adjacent to it in the electrostatic protective layer 2 may be set to be equal.

Further, referring to FIGS. 23-24, the electrostatic protective layer 2 may include a first surface 36 away from the side surface of the base substrate 1, a second surface 37 adjacent to the side surface of the base substrate 1, and a first side surface 38. Along the direction from the first surface 36 to the second surface 37, the first side surface 38 may be inclined toward the center of the electrostatic protective layer 2. The electrostatic conductive layer 4 may be connected to the first side surface 38.

When the first side surface 38 is designed as above, the anti-electrostatic layer 2 may have a large contact area with the electrostatic conductive layer 4 without expanding the base substrate 1 too much. First, the influence of the expansion of the anti-electrostatic layer 2 on the overall size of the panel may be reduced. When the display panel is used in a spliced display device, the splicing seam may be weakened. Second, the connection reliability between the anti-electrostatic layer 2 and the electrostatic conductive layer 4 may be increased.

In another embodiment, referring to FIGS. 23 and 24, the display panel may also include a side filling layer 39. The side filling layer 39 may be located between the electrostatic conductive layer 4 and the base substrate 1.

When the anti-electrostatic layer 2 is expanded and connected to the electrostatic conductive layer 4, there may be a gap between the electrostatic conductive layer 4 and the base substrate 1. At this time, the side filling layer 39 may be used to fill these gap grooves to prevent the electrostatic conductive layer 4 from breaking.

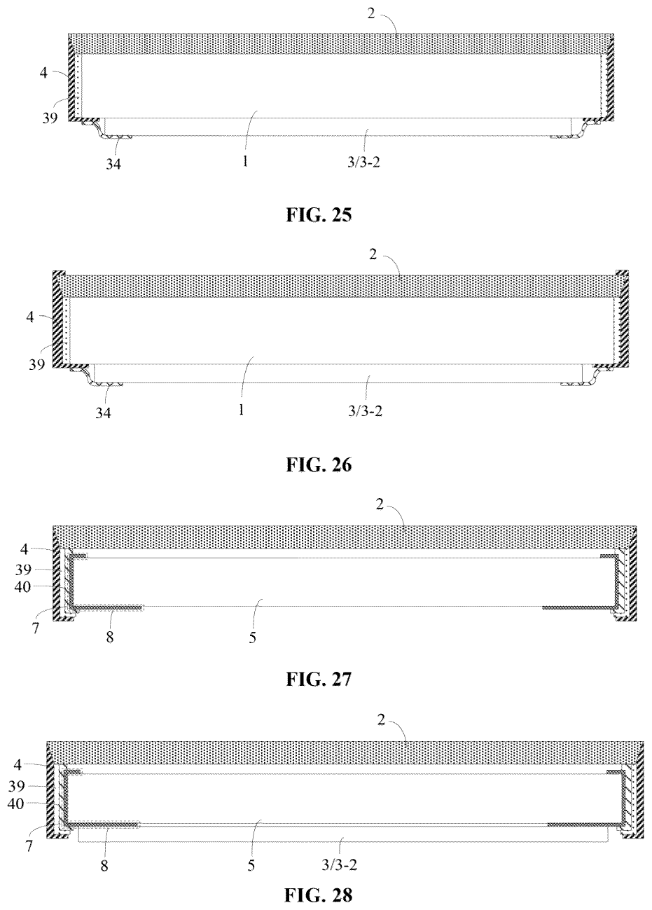

It should be noted that in the embodiment of the present disclosure, the side filling layer 39 may be partially located on the side surface of the base substrate 1 and partially located on the side of the base substrate 1 away from the anti-electrostatic layer 2. Alternatively, as shown in FIG. 25, which is another cross-sectional structural schematic diagram of an exemplary display panel provided by the embodiment of the present disclosure, and the side filling layer 39 may be located only on the side surface of the base substrate 1.

FIG. 26 is another cross-sectional structural schematic diagram of an exemplary display panel provided by one embodiment of the present invention. In one embodiment, as shown in FIG. 26, a portion of the electrostatic conductive layer 4 may also be located on the side of the electrostatic protective layer 2 away from the base substrate 1 such that the electrostatic conductive layer 4 may still be in contact with the electrostatic protective layer 2 above the electrostatic protective layer 2, further increasing the connection area between the electrostatic protective layer 2 and the electrostatic conductive layer 4, and improving the reliability of electrostatic discharge. The surface where the electrostatic protective layer 2 is located may be the light-exiting surface of the display panel, and the electrostatic conductive layer 4 may still be in contact with the electrostatic protective layer 2 above the electrostatic protective layer 2, which may mean that a portion of the electrostatic conductive layer 4 may also be arranged on the side of the light-exiting surface of the display panel.

In one embodiment of the present disclosure, the electrostatic conductive layer 4 may include a sealant material capable of conducting static electricity such that the electrostatic conductive layer 4 may also play the role of side encapsulation to prevent water and oxygen from penetrating into the base substrate 1 from the side surface.

FIG. 27 is another cross-sectional structural schematic diagram of an exemplary display panel provided by one embodiment of the present disclosure, and FIG. 28 is another cross-sectional structural schematic diagram of an exemplary display panel provided by one embodiment of the present disclosure. In combination with FIG. 20, as shown in FIG. 27 and FIG. 28, the base substrate 1 may include a substrate 5, a functional wiring 6, a first side wiring 7 and a fan-out wiring 8. The functional wiring 6 may be located on the side of the substrate 5 adjacent to the anti-electrostatic layer 2. The fan-out wiring 8 may be located on the side of the substrate 5 away from the anti-electrostatic layer 2. The functional wiring 6 may be connected to the fan-out wiring 8 through the first side wiring 7, and the first side wiring 7 may be at least located on the side of the substrate 5. The display panel may also include a side encapsulation layer 40. The side encapsulation layer 40 may be at least located on the side of the substrate 1 and cover the first side wiring 7.

When the first side wiring 7 is provided, the side encapsulation layer 40 may be further provided on the outside of the first side wiring 7. The side encapsulation layer 40 may be used to protect the first side wiring 7 from being scratched, and short-circuited, etc.

The side encapsulation layer 40 may be arranged around the base substrate 1, and the side encapsulation layer 40 may be arranged at the position where the side wiring is arranged and the position where the side wiring is not arranged. In some embodiments, the side encapsulation layer 40 may also be arranged only at the position where the side wiring is arranged.

Further, the square resistance of the side encapsulation layer 40 may be greater than 109 ohms/square. When the square resistance of the side encapsulation layer 40 is within such a range, the side encapsulation layer 40 may have a high resistance characteristic, which may shield the interference of the static electricity on the electrostatic conductive layer 4 to the wiring on the first side wiring 7.

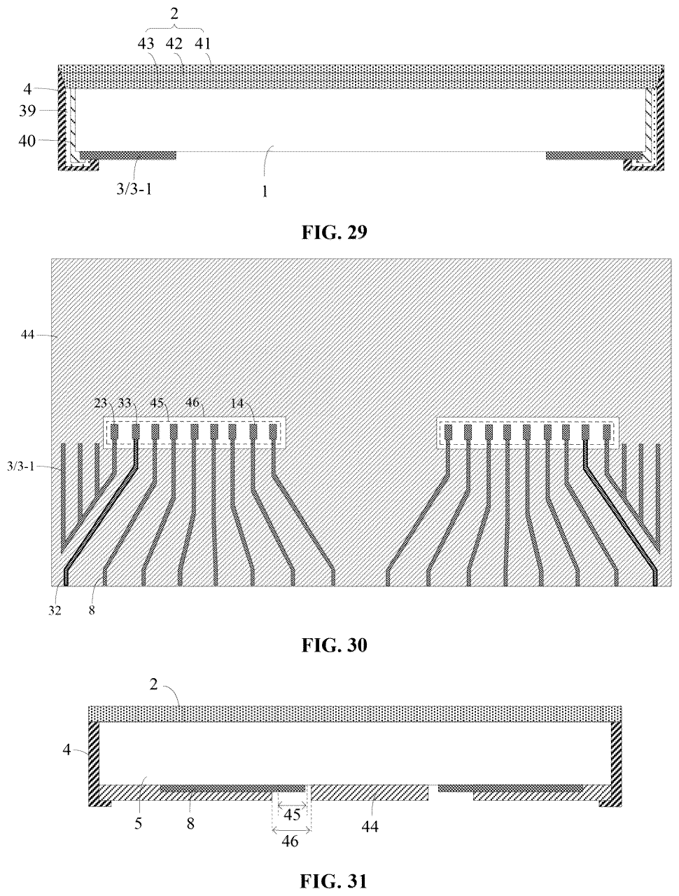

FIG. 29 is a cross-sectional structural schematic diagram of another display panel provided by an embodiment of the present disclosure. As shown in FIG. 29, in one embodiment the anti-electrostatic layer 2 may include at least one of an anti-fingerprint (AF) layer 41, an anti-glare (AG) layer 42 and an anti-reflection (AR) layer 43.

For example, in an embodiment of the present disclosure, the anti-electrostatic layer 2 may be an AG+AR+AF film material including an anti-fingerprint layer 41, an anti-glare layer 42 and an anti-reflection layer 43, also known as a 3A film material such that the anti-electrostatic layer 2 may have multiple properties such as anti-static, anti-reflection, anti-glare and anti-fingerprint, and the film material performance may be better.

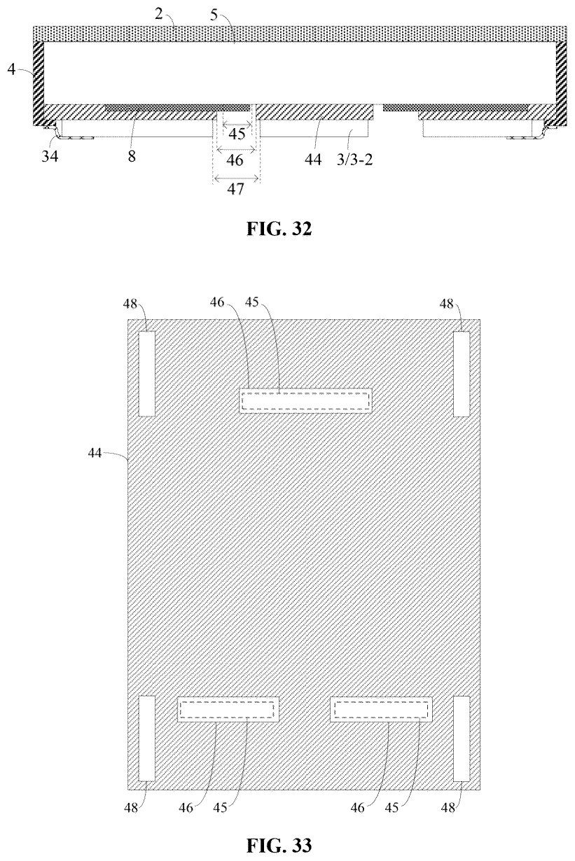

FIG. 30 is a structural schematic diagram of another exemplary display panel provided in an embodiment of the present disclosure. FIG. 31 is another cross-sectional structural schematic diagram of an exemplary display panel provided in an embodiment of the present disclosure. FIG. 32 is another cross-sectional structural schematic diagram of an exemplary display panel provided in an embodiment of the present disclosure. As shown in FIGS. 30-32, in one embodiment, the base substrate 1 may include a substrate 5 and a fan-out wiring 8. The fan-out wiring 8 may be located on the side of the substrate 5 away from the anti-electrostatic layer 2.

The display panel may also include a protective layer 44. At least a portion of the protective layer 44 may be located on the side of the fan-out wiring 8 away from the anti-electrostatic layer 2 to protect the fan-out wiring 8 and prevent the fan-out wiring 8 from being scratched or short-circuited.

The side of the substrate 5 away from the anti-electrostatic layer 2 may have a bonding area 45, and the bonding area 45 may include a fan-out pin 14, a first pin 23, and a second pin 33. The protective layer 44 may include a first hollowed structure 46, and the first hollowed structure 46 may expose the bonding area 45 such that the pins in the bonding area 45 may be exposed, which may be convenient for the pins to be bound to the driving structure.

It should be noted that, referring to FIG. 32, when the first structure 3 includes a first sub-structure 3-2, and the first sub-structure 3-2 may be located on the side of the protective layer 44 away from the substrate 5. At this time, the first sub-structure 3-2 may have a third hollowed structure 47. The third hollowed structure 47 may expose the bonding area 45 such that the pins in the bonding area 45 may be bound to the driving structure.

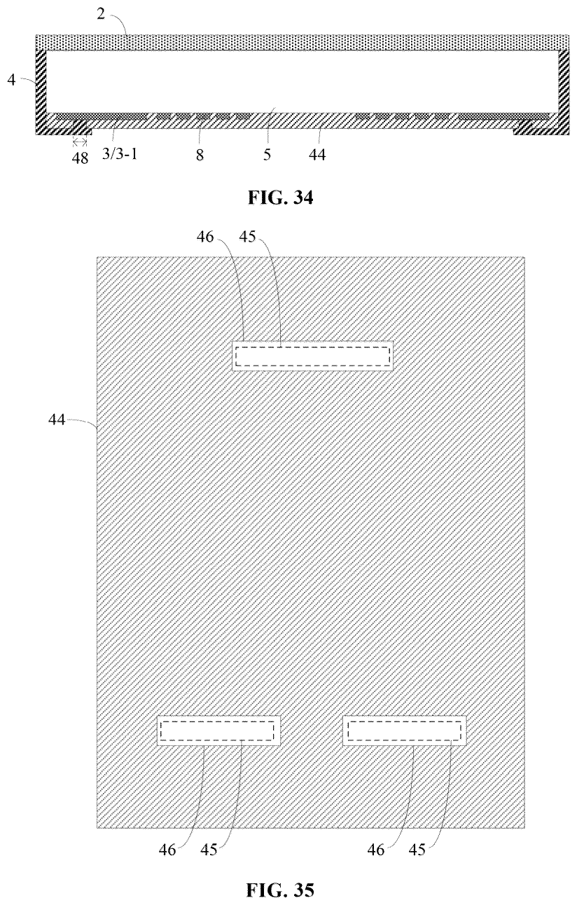

FIG. 33 is a schematic diagram of an exemplary structure of a protective layer 44 provided in one embodiment of the present disclosure. FIG. 34 is another schematic diagram of a cross-sectional structure of an exemplary display panel provided in one embodiment of the present disclosure. As shown in FIG. 33 and FIG. 34 and in combination with FIG. 2, in one embodiment of the present disclosure, the first structure 3 may include a metal part 3-1. The metal part 3-1 may be located on the side of the substrate 5 away from the anti-electrostatic layer 2. The metal part 3-1 may be arranged in the same layer as the fan-out wiring 8. A portion of the protective layer 44 may also be located on the side of the metal part 3-1 away from the anti-electrostatic layer 2 to protect the metal part 3-1 from being scratched.

In one embodiment, referring to FIG. 33 and FIG. 34, the protective layer 44 may also include a second hollowed structure 48. The second hollowed structure 48 may expose the area in the metal part 3-1 for connecting with the electrostatic conductive layer 4 such that the portion of the metal part 3-1 may be exposed, which may be convenient for connecting with the electrostatic conductive layer 4.

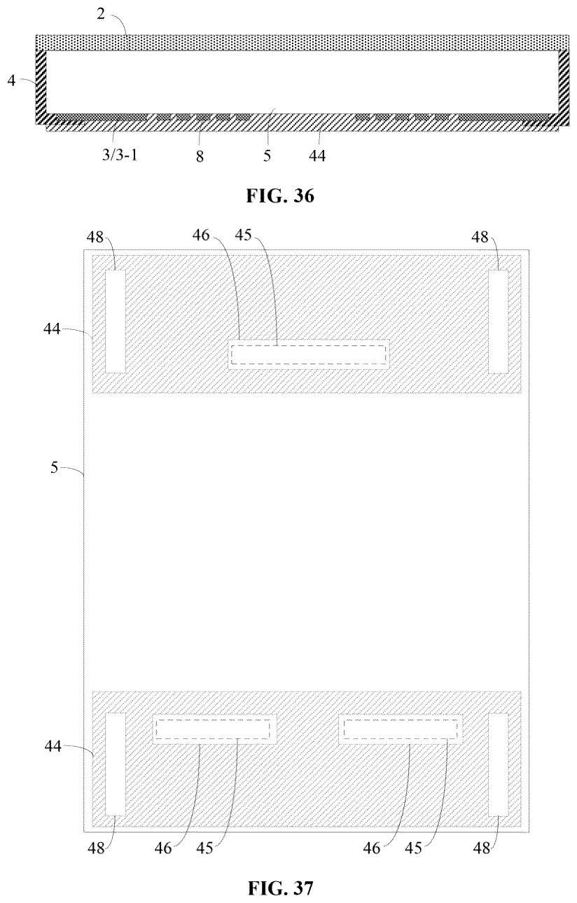

FIG. 35 is another exemplary structural schematic diagram of the protective layer 44 provided in one embodiment of the present disclosure. FIG. 36 is another cross-sectional structural schematic diagram of an exemplary display panel provided in one embodiment of the present disclosure. As shown in FIG. 35 and FIG. 36, in some embodiments, for the portion of the electrostatic conductive layer 4 located on the side of the base substrate 1 away from the electrostatic protective layer 2, the protective layer 44 may be located on the side of the portion of the electrostatic conductive layer 4 away from the electrostatic protective layer 2, that is, the protective layer 44 may be formed after the electrostatic conductive layer 4 is formed. In such a way, there may be no need to set the second hollowed structure 48 in the protective layer 44. Accordingly, the protective area of the protective layer 44 may be larger, and the connection area that the electrostatic conductive layer 4 and the metal part 3-1 may have may also be set larger.

In one embodiment of the present disclosure, the protective layer 44 may cover the entire surface of the base substrate 1, including only some of the above-mentioned smaller hollowed areas. FIG. 37 is another exemplary structural schematic diagram of the protective layer 44 provided in one embodiment of the present disclosure. As shown in FIG. 37, the display panel may include at least two protective layers 44. A single protective layer 44 may only be partially arranged on the back side of the base substrate 1. In one embodiment, to make the protective layer 44 have better corrosion resistance, wear resistance, and scratch resistance, the protective layer 44 may be formed by a screen-printing process.

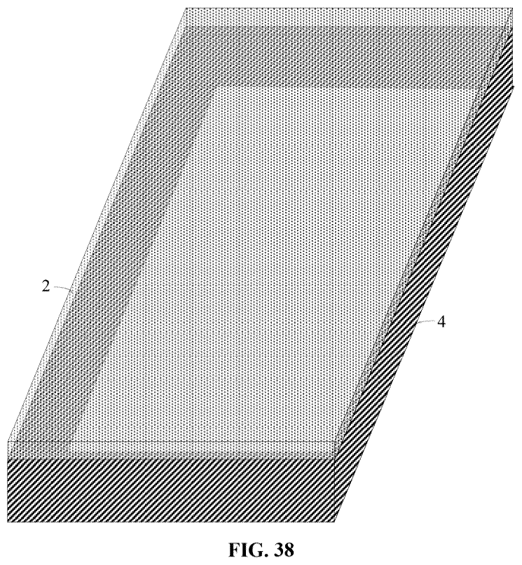

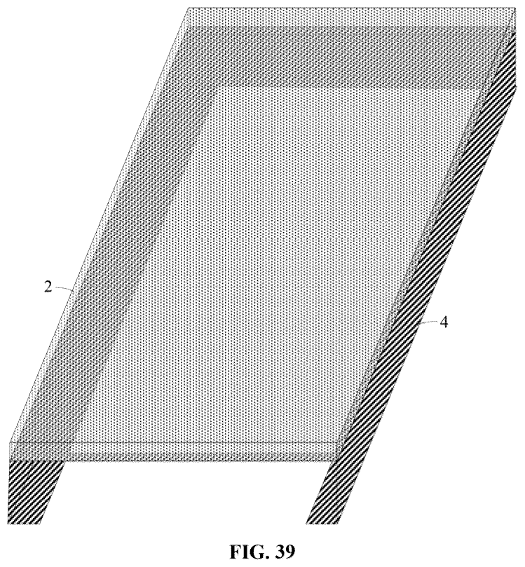

FIG. 38 is an exemplary structural schematic diagram of the anti-electrostatic layer 2 and the electrostatic conduction layer 4 provided in one embodiment of the present disclosure. FIG. 39 is another exemplary structural schematic diagram of the anti-electrostatic layer 2 and the electrostatic conduction layer 4 provided in one embodiment of the present disclosure. As shown in FIG. 38 and FIG. 39, in one embodiment, the electrostatic conduction layer 4 may be at least partially arranged around the edge of the base substrate 1.

The electrostatic conduction layer 4 may be at least partially arranged around the edge of the base substrate 1, including at least the following situations: the electrostatic conduction layer 4 may surround the substrate 1 in a whole circle, for example, in combination with FIG. 7 and FIG. 38, the substrate 5 may be provided with an electrostatic conduction layer on one side of the two first edges 15 and the two second edges 16. In some embodiments, the electrostatic conductive layer 4 may also be arranged only along a portion of the edge of the base substrate 1. For example, in combination with FIG. 10 and FIG. 39, among the two first edges 15, one first edge 15 may have a wiring area 9 on one side, and the other first edge 15 may have no wiring area 9 on one side. The electrostatic conductive layer 4 may be arranged only on the two second edges 16 and the first edge 15 that does not correspond to the wiring area 9, and not on the first edge 15 that corresponds to the wiring area 9 to further avoid the influence of static electricity on the first side wiring 7 during the release process. The electrostatic conductive layer 4 under this structure may be arranged continuously with a large area, and the distribution of static electricity in the electrostatic conductive layer 4 may be more dispersed and less likely to accumulate.

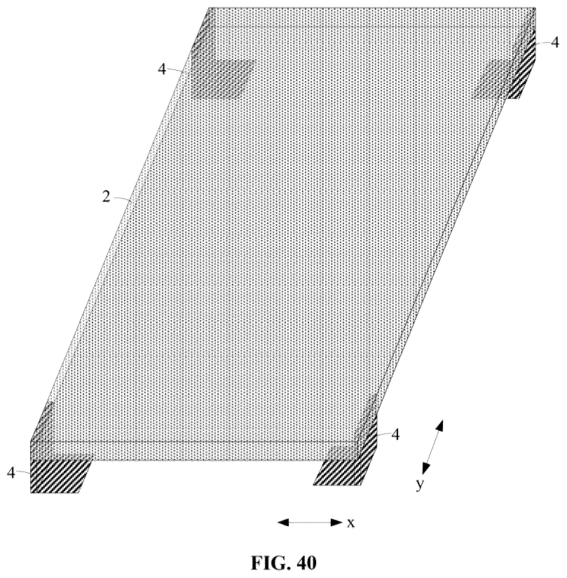

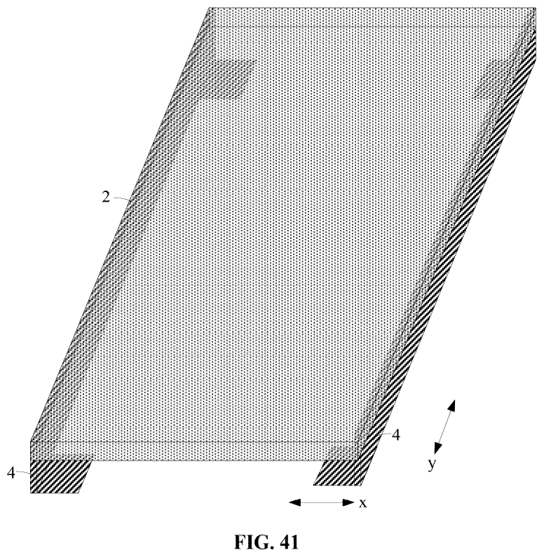

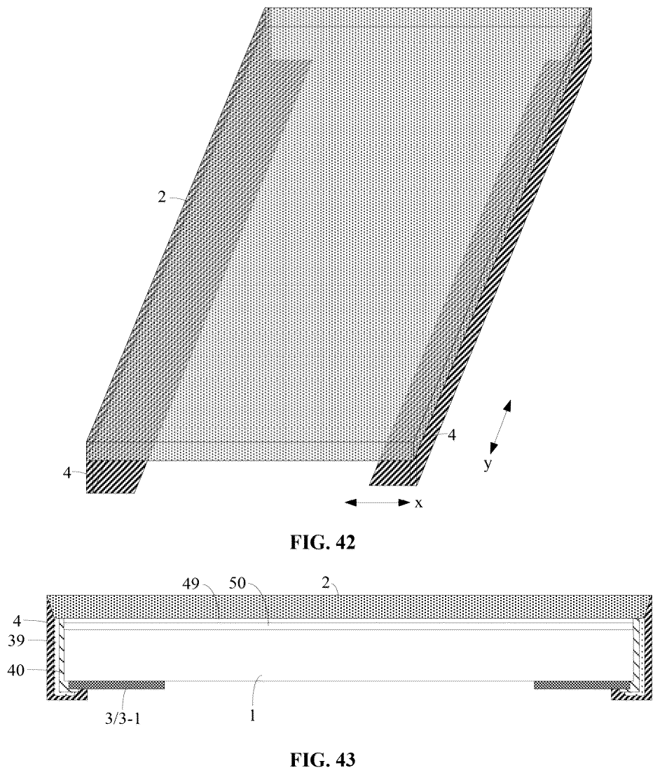

FIG. 40 is another exemplary structural schematic diagram of the anti-electrostatic layer 2 and the electrostatic conduction layer 4 provided in one embodiment of the present disclosure. FIG. 41 is another exemplary structural schematic diagram of the anti-electrostatic layer 2 and the electrostatic conduction layer 4 provided in one embodiment of the present disclosure. FIG. 42 is another exemplary structural schematic diagram of the anti-electrostatic layer 2 and the electrostatic conduction layer 4 provided in one embodiment of the present disclosure. As shown in FIGS. 40-42, in some embodiments, the display panel may include at least two electrostatic conduction layers 4 spaced from each other, and the at least two electrostatic conduction layers 4 may be respectively connected to the first structure 3 (not shown in FIG. 40 and FIG. 41).

In one embodiment, in combination with FIG. 2, the substrate 5 may include a first edge 15 extending along the first direction x and a second edge 16 extending along the second direction y. The first side wiring 7 may be located on the side where the first edge 15 is located.

The display panel may include at least two electrostatic conduction layers 4. A portion of the electrostatic conduction layer 4 may be located on the side where one second edge 16 is located, and the rest of the electrostatic conduction layer 4 may be located on the side where the other second edge 16 is located, that is, the electrostatic conduction layer may be only located at a position where no side wiring is set to avoid the influence of electrostatic conduction on the side wiring.

Further, it should be noted that when the electrostatic conductive layer 4 is connected to the metal part 3-1, the electrostatic conductive layer 4 may need to be bent from the side of the substrate 5 to the back of the base substrate 1 (the side of the base substrate 1 away from the anti-electrostatic layer 2) and then connected to the metal part 3-1. For this portion of the electrostatic conductive layer 4 located on the back of the base substrate 1, in combination with FIG. 42, this portion of the electrostatic conductive layer 4 may be extended in a strip shape along the second direction y to facilitate contact and connection with the metal part 3-1 over a larger area. In some embodiments, in combination with FIG. 41 and FIG. 4, this portion of the electrostatic conductive layer 4 may also be set only at the location where the metal part 3-1 is located, and not at the location where there is no metal part 3-1.

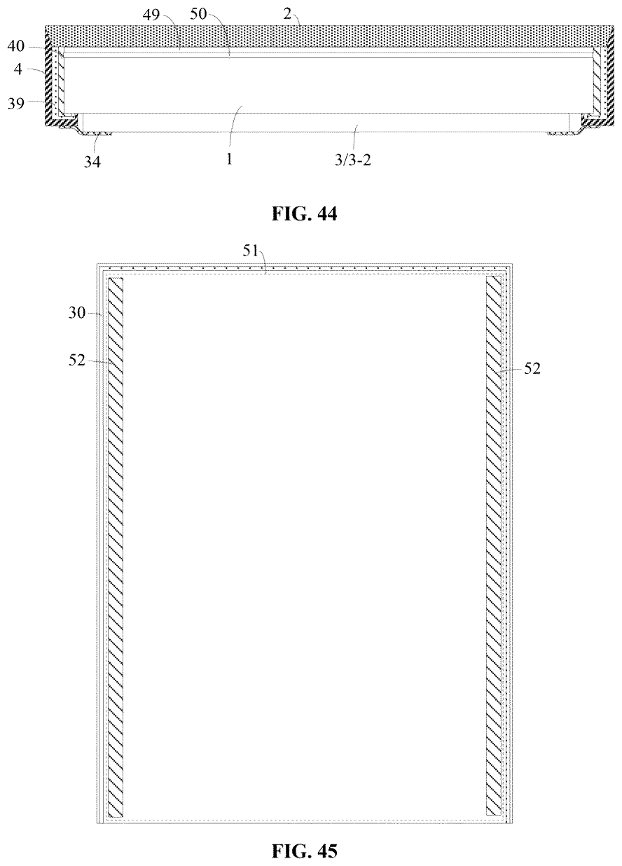

FIG. 43 is another exemplary cross-sectional structural schematic diagram of a display panel provided in one embodiment of the present disclosure. FIG. 44 is another exemplary cross-sectional structural schematic diagram of a display panel provided in one embodiment of the present disclosure. As shown in FIG. 43 and FIG. 44, in one embodiment, the display panel may also include a light-shielding layer 49. The light-shielding layer 49 may be located between the anti-electrostatic layer 2 and the base substrate 1. In another embodiment, the display panel may also include an ink layer 50. The link layer 50 may be located between the anti-electrostatic layer 2 and the base substrate 1.

The anti-electrostatic layer 2, the light-shielding layer 49 and the ink layer 50 may form a packaging structure. The light-shielding layer 49 may be used to shield the light, and may be a black matrix. The ink layer 50 may include a black ink material for shielding the area that does not need to be transparent. In some embodiments, the ink layer 50 may also include a transparent ink material for reducing the scattering and reflection of light.

FIG. 45 is another cross-sectional structural schematic diagram of the display panel provided by the embodiment of the present disclosure. As shown in FIG. 45, in one embodiment, the display panel may also include a display area 51 and a shift register 52. At least a portion of the shift register 52 may be located in the display area 51. Under such a configuration, the shift register 52 may occupy almost no frame space, and the display panel may realize an ultra-narrow frame or a frameless design.

In other words, under such a design, a portion of the frame space released by the shift register 52 may be used to accommodate the electrostatic ring 30 and the electrostatic conductive layer 4. For example, the electrostatic ring 30 may be located between the shift register 52 and the outer edge of the base substrate 1, and further between the display area 51 and the outer edge of the base substrate 1. Under the premise of ensuring that the display panel frame is still narrow, more turns of electrostatic rings 30 may be set to enable the base substrate 1 itself to achieve a better anti-static ability. In another embodiment, the electrostatic conductive layer 4 on the side of the base substrate 1 may be designed to be thicker to further accelerate the release of static electricity.

Further, it should be noted that FIG. 44 only simply illustrates that at least a portion of the shift register 52 is located in the display area 51, and does not mean a specific limitation on the setting position of the shift register 52. In one configuration, the shift register 52 may include a plurality of shift units arranged in cascade, and the plurality of shift units may be arranged between adjacent pixel circuit rows, thereby optimizing the arrangement between the shift register 52 and the pixel circuit.

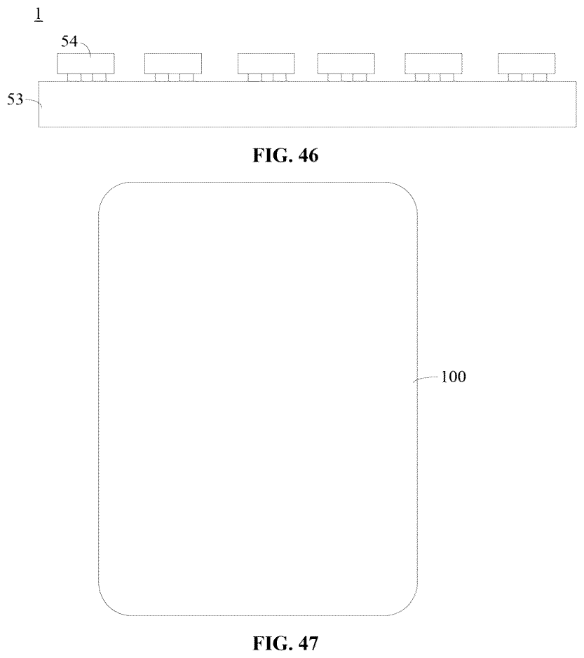

FIG. 46 is an exemplary structural schematic diagram of a base substrate 1 provided in one embodiment of the present disclosure. As shown in FIG. 46, in one embodiment, the base substrate 1 may include an array substrate 53 and a light-emitting diode 54 located on one side of the array substrate 53. The light-emitting diode 54 may be a mini-LED, or micro-LED, etc.

The array substrate 53 may include the aforementioned substrate 5, a functional wiring 6, a first side wiring 7, a fan-out wiring 8, an electrostatic ring 30, a second side wiring 31, a first connection line 32 and other structures. In addition, the array substrate 53 may also include multiple functional circuits, such as pixel circuits and shift registers 52, etc.

The present disclosure also provides a display device. FIG. 47 is a structural schematic diagram of an exemplary display device according to various disclosed embodiments of the present disclosure. As shown in FIG. 47, the display device may include the above-mentioned display panel 100. The display device shown in FIG. 47 is only for schematic illustration, and the display device may be any electronic device with display function, such as a mobile phone, a tablet computer, a laptop computer, an e-book, or a television, etc.

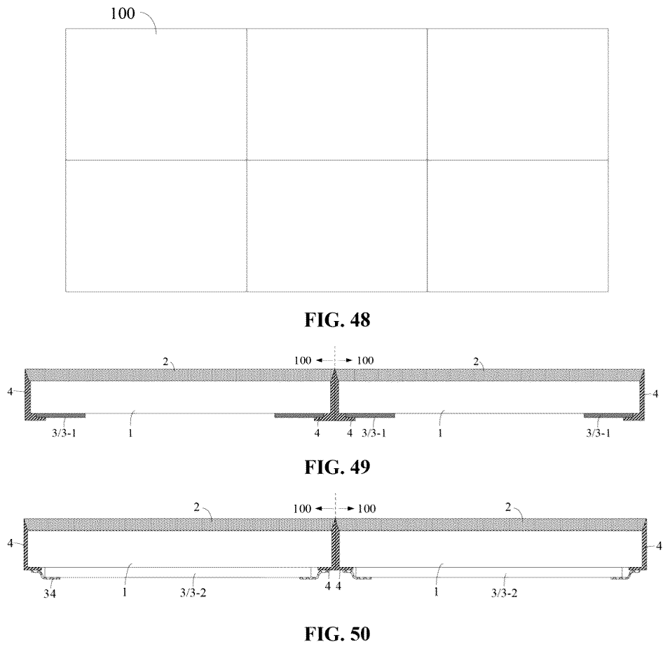

Further, the present disclosure also provides a spliced display device. FIG. 48 is a structural schematic diagram of an exemplary spliced display device provided by one embodiment of the present disclosure. FIG. 49 is a structural schematic diagram of another exemplary spliced display device provided by an embodiment of the present disclosure. FIG. 50 is a structural schematic diagram of another spliced display device provided by one embodiment of the present disclosure. As shown in FIGS. 48-50, the spliced display device may include at least two of the above-mentioned display panels 100.

The display panel 100 may include a spliced side. The spliced side may be a side where the display panel 100 is spliced with an adjacent display panel 100. At least a portion of the display panel 100 may also include a non-spliced side, and the display panel 100 may be not spliced with other display panel on the non-spliced side.

For at least a portion of the display panel 100, the electrostatic conductive layer 4 in the display panel 100 may be at least located on the spliced side of the display panel 100, and/or, for the at least portion of the display panel 100, the electrostatic conductive layer 4 in the display panel may be at least located on the non-spliced side of the display panel 100.

This type of spliced display device may be a spliced large screen, which may be used in public information display (PID) scenes such as stations and airports. When the spliced display device includes the above-mentioned display panel 100, the anti-static ability of the device may be effectively improved, thereby improving the display effect of the spliced display device.

In the technical solution provided by the embodiments of the present disclosure, the anti-electrostatic layer, the electrostatic conduction layer and the first structure may form an electrostatic release path, providing a good anti-static environment for the display panel. For the electrostatic charge generated on the surface of the display panel, this part of the electrostatic charge may be conducted to the electrostatic conduction layer through the anti-electrostatic layer, and then to the first structure, and may be released on the back side of the base substrate. For the electrostatic charge generated on the side surface of the display panel, this part of the electrostatic charge may be conducted to the first structure through the electrostatic conduction layer, and may release on the back side of the base substrate.

Further, based on the above-mentioned electrostatic release path, not only may the anti-electrostatic layer and the electrostatic conduction layer be used to protect the surface of the display panel to a large extent to prevent the electrostatic charge generated on the surface of the display panel from penetrating into the interior of the substrate, but also, when the static electricity is transmitted on this path, it may only flow from the side of the base substrate to the back side through the electrostatic conduction layer, and the static electricity may not be transmitted from the inside of the substrate. Accordingly, during its release process, it may also avoid affecting the devices and wiring inside the base substrate.

Compared with the method of realizing electrostatic protection only by relying on the electrostatic ring of the substrate itself, the technical solution provided by the embodiments of the present disclosure may make the display panel have a stronger anti-electrostatic ability, thereby avoiding the influence of static electricity on the display to a greater extent.

The above description is only a preferred embodiment of the present disclosure, and is not intended to limit the present disclosure. Any modifications, equivalent substitutions, improvements, etc. made within the spirit and principles of the present disclosure should be included in the scope of protection of the present disclosure.

Finally, it should be noted that the above embodiments are only used to illustrate the technical solutions of the present disclosure, rather than to limit the present disclosure. Although the present disclosure has been described in detail with reference to the above embodiments, those skilled in the art should understand that they can still modify the technical solutions described in the above embodiments, or replace part or all of the technical features therein by equivalents. However, these modifications or replacements do not make the essence of the corresponding technical solutions deviate from the scope of the technical solutions of the embodiments of the present disclosure.

What is claimed is:

1. A display panel, comprising:
a base substrate;
an anti-electrostatic layer located on one side of the base substrate; and
a first structure at least located on a side of the base substrate away from the anti-electrostatic layer,
wherein:
the anti-electrostatic layer is connected to the first structure via an electrostatic conductive layer; and
the electrostatic conductive layer is at least located on a side surface of the base substrate.

2. The display panel according to claim 1, wherein the base substrate comprises:
a substrate;
a functional wiring;
a first side wiring; and
a fan-out wiring,
wherein:
the functional wiring is located on a side of the substrate adjacent to the anti-electrostatic layer;
the fan-out wiring is located on a side of the substrate away from the anti-electrostatic layer;
the functional wiring is electrically connected to the fan-out wiring through the first side wiring;
the first side wiring is at least located on a side surface of the substrate;
the first structure includes a metal part;
the metal part is located on a side of the substrate away from the anti-electrostatic layer; and
the metal part is arranged on a same layer as the fan-out routing.

3. The display panel according to claim 2, wherein the substrate comprises:
at least one wiring area on a side the substrate away from the anti-electrostatic layer,
wherein:
the at least one wiring area includes a fan-out area and a non-fan-out area;
the fan-out wiring is located in the fan-out area;
the non-fan-out area includes a first non-fan-out area;
the metal part includes a first metal part; and
the first metal part is located in the first non-fan-out area.

4. The display panel according to claim 3, wherein the substrate comprises:
a first edge extending along a first direction and a second edge extending along a second direction,
wherein:
the first direction intersects with the second direction;
at least a portion of the first side wiring is electrically connected to the fan-out wiring on one side of the first edge;
the first non-fan-out area and the fan-out area are arranged along the first direction; and
the first non-fan-out area is adjacent to the second edge.

5. The display panel according to claim 4, wherein the wiring area comprises:
a first wiring area,
wherein:
the first wiring area includes at least two fan-out areas arranged along the first direction;
in the first wiring area, the non-fan-out area also includes at least one second non-fan-out area;
the at least one second non-fan-out area is located between adjacent fan-out areas of the at least two fan-out areas; and
a dummy metal is arranged in the at least one second non-fan-out area.

6. The display panel according to claim 3, wherein:
the first metal part includes a plurality of first wirings;
the plurality of first wirings are electrically to a plurality of second wirings;
the plurality of second wirings are connected to a plurality of first pins; and
the plurality of second wirings extend from between the plurality of first wirings and the fan-out wiring to the plurality of first pins and are connected to the plurality of first pins.

7. The display panel according to claim 2, wherein:
the substrate includes a first edge extending along a first direction and a second edge extending along a second direction;
the first direction intersects with the second direction;
at least a portion of the first side wiring is electrically connected to the fan-out wiring on one side of the first edge;
the substrate includes a fan-out area on a side of the substrate away from the anti-electrostatic layer;
the fan-out wiring is located in the fan-out area;
the metal part includes a second metal part;
the second metal part is adjacent to the second edge; and
the second metal part is not arranged with the fan-out area along the first direction; or
the substrate includes a first edge;
the base substrate also includes a connection portion located on a side of the substrate adjacent to the anti-electrostatic layer and adjacent to the first edge;
the functional wiring is electrically connected to the connection portion; and
at least a portion of the first side wiring is led out from the connection portion and extends from the side where the first edge is located to be electrically connected to the metal part.

8. The display panel according to claim 2, further comprising:
a second structure located at least on a side of the metal part away from the anti-electrostatic layer,
wherein:
the electrostatic conductive layer and/or the metal part are also connected to the second structure via a first conductive connection structure; and
the second structure includes at least one of a heat dissipation structure, a support structure, a back plate and a frame.

9. The display panel according to claim 1, wherein the base substrate comprises:
a substrate;
an electrostatic ring;
a second side wiring; and
a first connection wiring,
wherein:
the electrostatic ring is located on a side of the substrate adjacent to the anti-electrostatic layer and extends around an edge of the substrate;
the first connection wiring is located on a side of the substrate away from the anti-electrostatic layer and is electrically connected to a second pin;
the electrostatic ring is connected to the first connection wiring through the second side wiring; and
the second side wiring is at least located on the side surface of the substrate.

10. The display panel according to claim 9, wherein the base substrate further comprises:
a functional wiring;
a first side wiring; and
a fan-out routing,
wherein:
the functional wiring is located on a side of the substrate adjacent to the anti-electrostatic layer;
the fan-out wiring is located on a side of the substrate away from the anti-electrostatic layer;
the functional wiring is connected to the fan-out wiring through the first side wiring;
the first side wiring is at least located on the side surface of the substrate;
the first structure includes a metal part;
the metal part is located on a side of the substrate away from the anti-electrostatic layer;
the metal part and the fan-out wiring are arranged in a same layer; and
the first connection wiring extends from between the metal part and the fan-out wiring to be electrically connected to the second pin.

11. The display panel according to claim 10, wherein:
the metal part is electrically connected to the first pin, wherein a voltage provided by the driving structure to the first pin is greater than a voltage provided by the driving structure to the second pin.

12. The display panel according to claim 1, wherein the base substrate comprises:
a substrate;
a functional wiring;
a first side wiring; and
a fan-out routing,
wherein:
the functional wiring is located on a side of the substrate adjacent to the anti-electrostatic layer;
the fan-out wiring is located on a side of the substrate away from the anti-electrostatic layer;
the functional wiring is electrically connected to the fan-out wiring through the first side wiring;
the first side wiring is at least located on the side surface of the substrate;
the first structure includes a first sub-structure; and
the first sub-structure is located on a side of the fan-out wiring away from the substrate.

13. The display panel according to claim 12, wherein:
the electrostatic conductive layer is connected to the first sub-structure through a second conductive connection structure; and
a portion of the second conductive connection structure connected to the electrostatic conductive layer is located on a side of the electrostatic conductive layer away from the base substrate.

14. The display panel according to claim 13, wherein:
the electrostatic conductive layer includes a first section;
the first section is located on the side surface of the base substrate; and
the second conductive connection structure is also located on a side of the first section away from the base substrate.

15. The display panel according to claim 1, wherein:
a sheet resistance of the anti-electrostatic layer is greater than or equal to 10⁴ ohms/square and less than or equal to 10⁹ ohms/square; or
a sheet resistance of the electrostatic conductive layer is greater than or equal to 10⁴ ohms/square and less than or equal to 10⁹ ohms/square; or
a sheet resistance of the electrostatic conductive layer is smaller than a sheet resistance of the anti-electrostatic layer.

16. The display panel according to claim 1, wherein:
an edge portion of the anti-electrostatic layer protrudes from the base substrate;
the electrostatic conductive layer is at least connected to a protruding portion of the anti-electrostatic layer;
the anti-electrostatic layer;
the anti-electrostatic layer includes a first surface away from the base substrate;
a second surface adjacent to the base substrate, and a first side surface;
the first side surface is inclined toward a center of the anti-electrostatic layer along the direction from the first surface to the second surface; and
the electrostatic conductive layer is connected to the first side surface, or
the display panel includes a side filling layer located between the electrostatic conductive layer and the base substrate.

17. The display panel according to claim 1, wherein:
a portion of the electrostatic conductive layer is also located on a side of the anti-electrostatic layer away from the base substrate; or
the base substrate incudes a substrate, a functional wiring, a first side wiring, and a fan-out wiring;
the functional wiring is located on a side of the substrate adjacent to the anti-electrostatic layer;
the fan-out wiring is located on a side of the substrate away from the anti-electrostatic layer;
the functional wiring is connected to the fan-out wiring through the first side wiring;
the first side wiring is at least located on the side surface of the substrate; and
the display panel also includes a side packaging layer at least located on the side surface of the base substrate and covering the first side wiring.

18. The display panel according to claim 1, wherein the base substrate comprises:
a substrate; and
a fan-out wiring,
wherein:
the fan-out wiring is located on a side of the substrate away from the anti-electrostatic layer;
the display panel also includes a protective layer;
at least portion of the protective layer is located on a side of the fan-out wiring away from the anti-electrostatic layer;
a side of the substrate away from the anti-electrostatic layer includes a bonding area;
the protective layer includes a first hollowed structure; and
the first hollowed structure exposes the bonding area.

19. The display panel according to claim 18, wherein the first structure comprises:
a metal part located on a side of the substrate away from the anti-electrostatic layer and arranged on a same layer as the fan-out wiring,
wherein:
a portion of the protection layer is also located on a side of the metal part away from the anti-electrostatic layer; and
the protection layer also includes a second hollowed structure exposing an area in the metal part for connecting to the electrostatic conductive layer.

20. A display device, comprising:
a display panel, including:
a base substrate;
an anti-electrostatic layer located on one side of the base substrate; and
a first structure located at least on a side of the base substrate away from the anti-electrostatic layer,
wherein:
the anti-electrostatic layer is connected to the first structure via an electrostatic conductive layer; and
the electrostatic conductive layer is located at least on a side surface of the base substrate.
